(19) United States
(12) Patent Application Publication
(10) Pub. No.: US 2005/0220158 A1
(43) Pub. Date: Oct. 6, 2005

(54) Optical integrated device

(76) Inventors: Kenji Koyama, Yokohama-shi (JP); Jun-ichi Hashimoto, Yokohama-shi (JP); Tsukuru Katsuyama, Yokohama-shi (JP)

Correspondence Address: SMITH, GAMBRELL & RUSSELL, LLP, 1850 M STREET, N.W., SUITE 800, WASHINGTON, DC, 20036, US

(21) Appl. No.: 11/091,337

(22) Filed: Mar. 29, 2005

(30) Foreign Application Priority Data
Mar. 30, 2004 (JP) 2004-099904

(51) Int. Cl. H01S 5/00

(52) U.S. Cl. 372/43.01

(57) ABSTRACT

The present invention is to provide an optical integrated device formed on the GaAs substrate and with reduced dispersion of the optical coupling of the but-joint between the active and the passive devices. The GaAs substrate of the invention is divided into two regions, and the lower cladding layer extends over both regions. The active layer, having a quantum well structure with band-gap energy smaller than 1.3 eV, is arranged of the lower cladding layer in the first region, while the GaAs core layer is also arranged on the lower cladding layer but in the second region thereof. Thus, the cure layer may optically couple with the active layer.

### BACKGROUDN OF THE INVENTION

1. Field of the Invention

The present invention relates to an optical device that monolithically integrates an optically active device and an optically passive device.

2. Related Prior Art

Japanese patent published as H11-087844 has disclosed an optical integrated device, which is firmed on an InP substrate, including a plurality of optical waveguides connected in serial to each other. The waveguide in an active device comprises an InP active layer and an InP cladding layer, while the waveguide in a passive device includes an InP core and an InP cladding layer. On the InP substrate is provided with an etch-stopping layer made of InGaAsP. Because of the existence of this etch-stopping layer, a semiconductor surface without etching damage may be obtained when the semiconductor layers in the active device are removed by etching. On this damage-free surface is grown with the InP core and the InP cladding layer or the passive device. By using this etch-stopping layer, the patent above referred has solved geometrical subjects, such as concave or concave shape of the optical coupling surface due to considerable side etching, and optical problems derived from such geometrical subjects.

Optical integrated device applicable in a wavelength range longer than 1 μm may be processed on currently available InP substrate with 3-inch diameter. A semiconductor materials with greater band-gap energy than that of InP does not lattice-match to InP. Accordingly, in the InP system, which means that semiconductor materials considered have a lattice constant matching to that of Inp, materials having comparably greater band-gap energy may not apply to the optical confinement layer and the cladding layer. This means that the band-gap difference between the active layer and layers surrounding the active layer, such as cladding layer and optical confinement layer, is not ensured, thereby reducing the carrier confinement into the active region and degrading the performance of the device against the temperature.

An optical integrated device applicable in the longer wavelength band may be formed on the GaAs substrate. This integrated device includes binary or more complex group III-V semiconductor material composing nitrogen (N). For the optical integrated device with a butt joint structure, two-step growth is often used. That is, semiconductor layers for one of the waveguide are grown after the growth of layers for the other waveguide. The layers later grown are occasionally formed on the layers former grown. The layers grown later, at least a portion of the layer adjacent to the interface inevitably shows inhomogeneous composition and thickness. Therefore, the optical coupling efficiency of the devices is likely to scatter.

### SUMMARY OF THE INVENTION

The present invention is to solve the above subject and to provide an optical integrated device, which is formed on the GaAs substrate and has substantially uniform coupling efficiency in the butt joint structure.

An optical integrated device of the present invention comprises a GaAs substrate, first to third cladding layers, an active layer and a core layer. The GaAs substrate includes a first region for the first device, an active device, and a second region for the second device, a passive device. The first cladding layer extends over the first and second region of the substrate, while the active layer is fired only on the first region and the core layer is formed only on the second region. The second cladding layer is arranged on the active layer, and the third cladding layer is arranged on the core layer.

In the optical integrated device thus configured, since first device and the passive device are formed on the unique and common lower cladding layer, the thickness of the active layer and that of the core layer may be formed in identical to each other, even the active and core layers are grown by respective processes.

The optical integrated device of the present invention may further include an optical confinement layer. At least between the active layer and the lower cladding layer, or between the active layer and the second cladding layer is provided the optical confinement layer to confine light within this confinement layer and the quantum well and this active layer while the carriers injected from the electrode concentrate in the quantum well structure.

The active layer may include a semiconductor material belonging to the group III-V compound semiconductor and composing at least nitrogen (N), or composing at least gallium (Ga), arsenic (As) and nitrogen (N). These semiconductor materials have a lattice constant substantial matching to that of the GaAs. Moreover, these materials may widely vary the band-gap energy thereof with keeping the lattice constant substantially matching to that of the GaAs.

The first cladding layer extending over the first and second regions of the GaAs substrate may be GaInP with a lattice constant substantially matching to that of the GaAs. Since the GaInP and materials above constituting the quantum well layer may make the difference of the energy-gap therebetween, the configuration of the quantum well structure sandwiched by the GaInP cladding layer effectively confines not only the carriers but also the light within the quantum well layer.

Moreover, the core layer of the present invention may include first and second core layers. The first core layer has the second conduction type, for instant p-type, while the second core layer has the first conduction type, for instant n-type, and the second core layer is arranged on the first core layer to make the junction therebetween. Therefore, these double core layer may be biased in reverse when the first device including the active layer is biased in forward, which reduces the leak current for the active layer flowing in the core layer.

The active layer may have an end surface with a (111) crystallographic surface, which makes an angle, not a right angle, against the layer direction. The core layer may cover this (111) end surface to couple in optical with the active layer. The light processed in the active layer is reflected at this end surface, but the reflected light does not reenter the active layer. Similarly, the light processed in the core layer is reflected at this end surface, but does not reenter the core layer, which reduces the optical noise in the active or in the core layer.

### BRIEF DESCRIPTION OF DRAWINGS

FIG. 1A is a perspective view showing an optical integrated device according to the first embodiment of the present invention, and FIG. 1B shows a structure of the active layer of the integrated device shown in FIG. 1A;

FIG. 2A is a cross section of the integrated device taken along the line I-I in FIG. 1A, and FIG. 2B shows a modified layer structure of the integrated device of the first embodiment;

from FIG. 3A to FIG. 3D show processes for manufacturing the integrated device according to the second embodiment of the invention;

from FIG. 4A to FIG. 4E show processes, subsequent to FIG. 3D, for manufacturing the integrated device of the invention;

from FIG. 5A to FIG. 5D show processes, the latter half thereof, for manufacturing the optical integrated device of the invention;

FIG. 6A is a perspective view showing an optical integrated device according to the second embodiment of the invention, and FIG. 6B shows a structure of the active layer of the integrated device;

FIG. 7 shows a cross section of the integrated device modified from those shown in FIG. 6A;

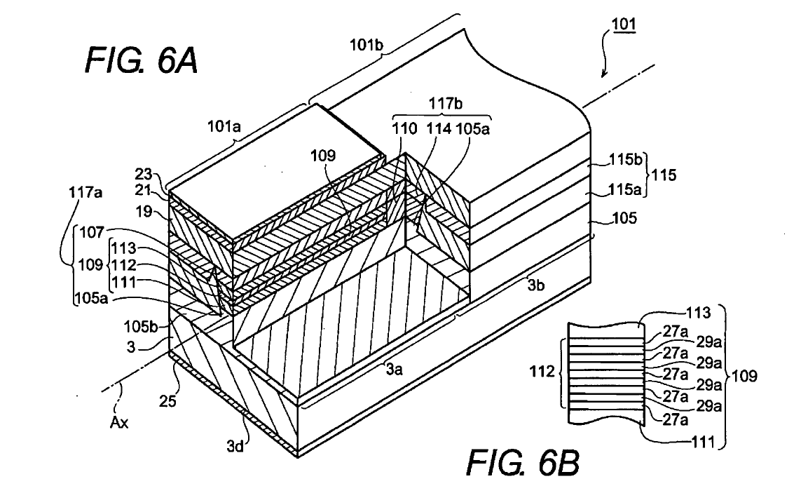

from FIG. 8A to FIG. 8F show processes for manufacturing the optical device shown in FIG. 6A according to the fourth embodiment of the invention and

from FIG. 9A to FIG. 9D shown processes, the latter half thereof for the manufacturing the optical integrated device shown in FIG. 6A.

### DESCRIPTION OF PREFERRED EMBODIMENTS

Spirits of the present invention will be easily understood by the following description as referring to accompanying drawings. Next, an optical integrated device of the invention will be described as referring to accompanying drawings. In the explanations and the drawings, if possible, same elements will be referred by same symbols or numerals without overlapping explanation.

### First Embodiment

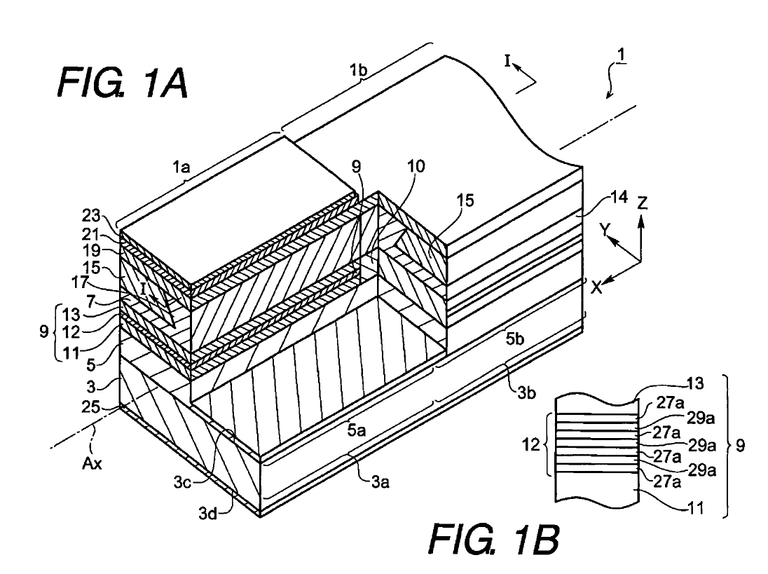

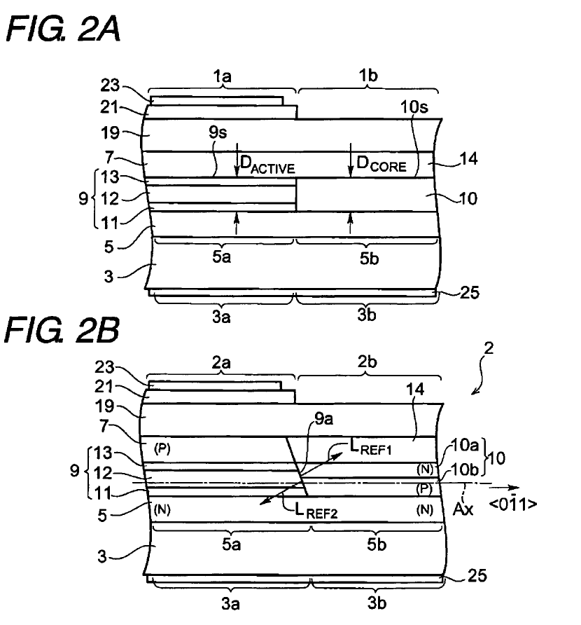

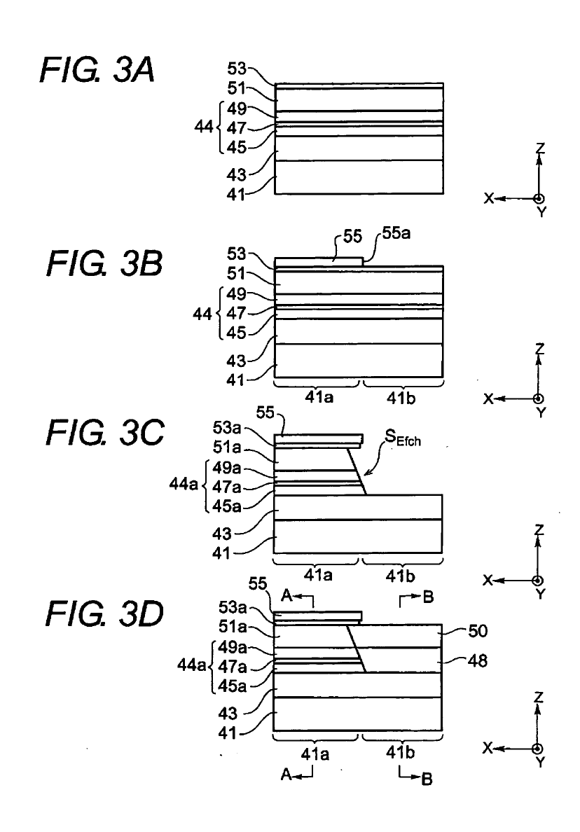

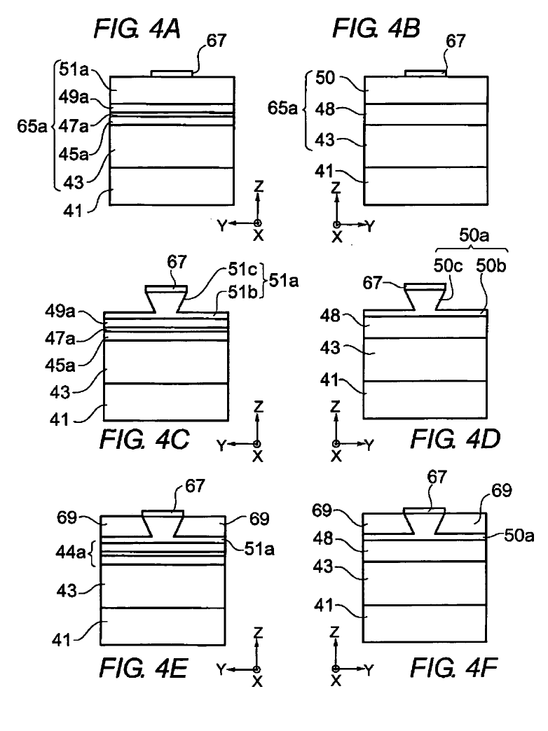

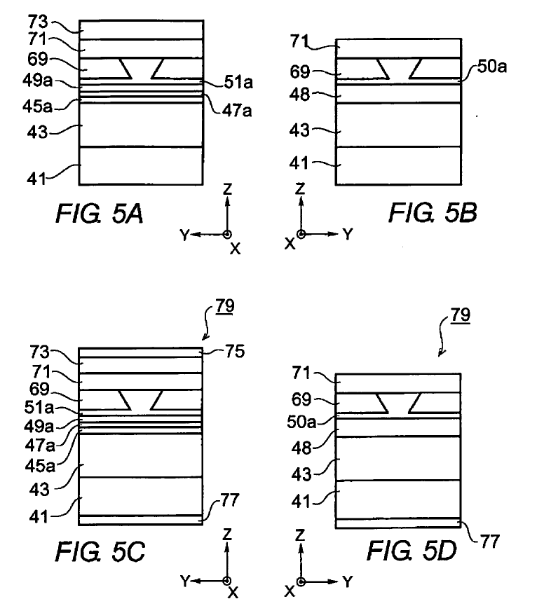

FIG. 1A is a perspective view showing an optical integrated device 1 according to the present invention, and FIG. 1B is a schematic diagram of an active layer of the optical integrated device 1. FIG. 2A is a cross section taken along the line I-I in FIG. 1A.

The optical integrated device 1 comprises a GaAs substrate 3, a first cladding layer 5, a second cladding layer 7, an active layer 9, a core layer 10 made of GaAs, and a third cladding layer 14. The GaAs substrate, whose primary surface 3c is (100) crystallographic face and has a first conduction type, for instance n-type, provides first and second regions, 3a and 3b, arranged along an axis Ax. The first cladding layer 5, showing the first conduction type, comprises a first portion 5a in the first region 3a and a second portion 5b in the second region 3b. The thickness of respective regions, 5a and 5b, are substantially equal to each other. The active layer 9, having band-gap energy smaller than 1.3 eV, which is equivalent to the wavelength 0.95 μm, is disposed on the first portion 5a of the first cladding layer 5. The active layer 9 may include a quantum well structure. The second cladding layer 7, showing a second conduction type, for instant p-type, is disposed on the active layer 9. The core layer 10, arranged on the second portion 5b of the first cladding layer 5, is butt-jointed to the active layer 9. The third cladding layer 14 is arranged on the core layer 10.

The active layer 9 of the first device 1a has a quantum well structure shown in FIG. 1B, which may be a signal-quantum well or a multi-quantum well. The quantum well structure in the active layer 9 comprises well layers 27a and barrier layers 27b alternately stacked to each other. In this device 1, the band-gap energy of the active layer 9 is smaller than that of the core layer 10.

As shown in FIG. 2A, the thickness of the core layer 10, D_{CORE}, is equal in substantial to the thickness of the active layer 9, D_{ACTIVE} to compensate the gap appeared in the mode field diameter in respective devices 1a and 1b, thereby reducing the optical coupling loss therebetween. When the core layer 10 is grown by an ordinal technique, such as organic metal vapor phase epitaxy (OMVPE) so as to coincide in the thickness thereof D_{CORE} to the thickness D_{ACTIVE} of the active layer 9, the upper level 10s of the core layer 10 becomes, within ±10 nm, equal to the upper level 9a of the active layer 9.

The active layer 9 may be a group III-V compound semiconductor material composing of nitrogen (N), or may be a semiconductor material composing of nitrogen (N), gallium (Ga) and arsine (As). Since the semiconductor material grouped in the III-V compound semiconductor and containing nitrogen (N) may have a lattice constant substantially matching to the GaAs substrate, accordingly, such semiconductor materials may be easily grown on the GaAs substrate 3. Moreover, such materials may have wide range of band-gap energy by adjusting the composition thereof with maintaining the lattice constant substantially matching to the GaAs.

In the present device, such semiconductor materials for the active layer 9 may compose of at least one of antimony (Sb) and phosphorus (P). Even when these elements are involved in the active layer 9, the lattice constant thereof may be left as substantially matching to the GaAs. The antimony (Sb) operates as a surfactant, which suppresses three dimensional growth of the semiconductor layer containing nitrogen (N), thereby improving the crystal quality. The phosphorous (P) may reduce the localized crystal deformation and may enhance the capture of the nitrogen into the crystal.

The active layer 9 may be GaNAs, GaInNAs, GaNAsSb, GaNAsP, GaNAsSbP, GaInNAsb, GaInNAsP, and GaInNAsSbP. These semiconductor materials have the lattice constant substantially equal to or similar to that of GaAs, and may widely vary their band-gap energy by adjusting the composition of respective elements.

The first and second cladding layers, 5 and 7, have band-gap energy greater than that of the active layer 9, which enables carriers to be confined in the active layer 9. Moreover, refractive indices of the first and second cladding layers, 5 and 7, are smaller than that of the active layer, which confines light within the active layer 9. These cladding layers, 5 and 7, may be one of or a combination of AlGaInP, GaInP, and AlGaAs. In particular, the first cladding layer 5 is preferably made of GaInP. Although ternary compound material the composition of the GaInP lattice-matching to the GaAs is defined without ambiguity, thus, the homogeneity in the composition thereof may be enhanced. Moreover, since the GaInP done not contains aluminum as a group III material, the oxidization and the abnormal growth of layers, they arise from aluminum element, can be prevented.

The active layer 9 of the device 1 may comprise a first and a second optical confinement layers, 11 and 13, respectively, and a quantum well layer 12 sandwiched by the optical confinement layers 11 and 13. These layers are formed on the first region 3a of the GaAs substrate 3. The band-gap energy of the optical confinement layers, 11 and 13, is smaller than that of the first and second cladding layers, 5 and 7, respectively. The optical confinement layers, 11 and 13 confine carriers within the quantum well layer 12, while first and second cladding layers, 5 and 7, confine light within in the optical confinement layers, 11 and 13, and the active layer 9. The optical confinement layers, 11 and 13, may be GaInAsP.

The core layer 10 of the present device 1 butts not only the active layer 9 but optical confinement layers, 11 and 13, of the first device 1a, accordingly, the optical coupling loss may be reduced between the first and second devices, 1a and 1b.

The optical integrated device 1 further comprises a current blocking layer 15 arranged on the second cladding layer 7 to bury the ridge 17 therein. The current blocking layer 15 may be a semiconductor material with high resistivity to concentrate into the ridge 17. On the current blocking layer 15 and the ridge 17 are provided with a fourth cladding layer 19 with the second conduction type and a refractive index smaller than that of the active region 9 and the core layer 10. The current blocking layer 15 may be one of, or a combination of AlGaInP, GaInP, and AlGaAs. These materials provide the current blocking layer with greater band-gap energy.

On the fourth cladding layer 19 is provided with a contact layer 21 having the second conduction type and low resistivity. The first device 1a provides first and second electrodes, 23 and 25, restively. The first electrode 23 is formed on the contact layer 21, while the second electrode 25 is on the back surface 3d of the GaAs substrate 3. When the first conduction type is n-type, the first and second electrodes, 23 and 26, function as an anode and a cathode, respectively.

FIG. 2B is a cross section of an optical integrated device 2 having a layer structure modified from that shown in FIG. 2A In the device 2, the core layer 10 includes a first core layer 10a with the first conduction type, for instance the n-type, and, arranged below this first core layer 10a, a second core layer 10b with the second conduction type, for instance the p-type. These two core layers, 10a and 10b, forms the pn-junction. The second core layer 10b (p-type) is sandwiched by the first cladding layer 5 (n-type) and the first core layer 10a (n-type). This layer configuration in the second region 3b can prevent the leak current flowing from the active layer 9 to the first cladding layer 5 via the core layer 10, because the junction formed between two core layers forms the pn-junction biased in reverse. Moreover, the small contact area between the core layer 10 and the second cladding layer 7 may further reduce the leak current.

The active layer 9 in FIG. 2B provides an end surface 9a optically coupled to the core layer 10. This end surface 9a includes the (111) crystallographic surface and is covered by the core layer 10. The (111) surface shows a normal slope, i.e. no overhung, thereby preventing voids from generating at the interface during the epitaxial growth. Since the (111) surface inclines to the prescribed axis Ax, though slight reflection occurred thereat, the reflected light, L_{REF1} and L_{REF2}, do not reenter the active layer 9 or the core layer 10. That is, for the light processed in the first device 1a, though slightly reflected at the surface 9a, the greater part thereof enters the waveguide in the second device 1b. For the light processed in the second device 2b, though slightly reflected at the surface 9a, most of it enters the waveguide of the first device 1a. The axis Ax is in parallel to the <1-10> crystal orientation.

### Second Embodiment

Next, a process, in the first half, for manufacturing the optical integrated device on in FIG. 1A will be described as referring to drawings from FIG. 3A to FIG. 3D.

As shown in FIG. 3A, a plurality of semiconductor layers is grown on the GaAs substrate 41. First, the first cladding layer 43, the active layer 44, the second cladding layer 51 and the cap layer 53 are grown in successive on the GaAs substrate 41. The active layer 44 includes the first optical confinement layer 45, the quantum well layer 47, and the second optical confinement layer 49. The GaAs wafer 41 and the first cladding layer 43 have the first conduction type, while the second cladding layer 61 has the set conduction type. The cap layer 63 may be GaAs. The first device 1a is to be formed on the region 41a, while the second device 1b is to be formed on the second region 41b. In FIG. 3A, the optical confinement layers, 45 and 49 are 150 nm thick GaAs, the second cladding layer 51 is 1500 nm thick GaInP, the quantum well layer 47 is 1 nm thick GaInNAs, and the cap layer is 100 nm thick GaAs.

In FIG. 3B, a mask 55, made of SiN, is formed on the first region 41a. The edge 55a of the mask 55 extends along the (0,−1,−1) surface, including its equivalent surfaces, thus the butted surface between two devices extends along the (0,−1,−1) surface.

In FIG. 3C, layers for the cap 53, the second cladding 51 and the active layer 44, which includes two optical confinement layers, 49 and 45, are removed to form the second device, which leaves a plurality of layers 44a, 51a and 53a, in the first region 41a. In FIG. 3a), layers from the core layer 48 and the third cladding layer 50 are selectively grown only in the second region without removing the mask 55. Since the first cladding layer 43 extends over the first and second region of the substrate 41, the care layer 48 may be grown so as to coincide in the thickness with the active layer 44a, by conventional technique such as the Organo-Metallic Chemical Vapor Phase Epitaxy.

Next, the latter half of the process will be described as referring to drawings from FIG. 4A to FIG. 5D. FIG. 4A shows the process for the first device, ie. the cross section taken along the line A-A, while FIG. 4B shows the same process for the second device, i.e., it shows the cross section taken along the line B-B of the second device. As shown in FIG. 4A and FIG. 4B, a mask 67 with a stripe and made of insulating film such as SiO₂ or SiN is formed on the semiconductor layers 65a and 65b.

Using this mask 67 and an adequate etchant, a portion of the second and third adding layers, 51 and 50 are etched to leave the etched first cladding layer 51a on the optical confinement layer 49, as shown in FIG. 4C and FIG. 4D. The left first cladding layer 51a includes a first portion 51b covering the optical confinement layer 49 and a second portion 51c having a ridge stripe extending the axis A. The etched third cladding layer 50a includes a first portion 50b covering the core layer 58 and a second portion 50c arranged on the first portion 50b. The shape of respective second portions, 50c and 51c, depends on the orientation of the axis A and the etchant.

Next, as shown in FIG. 4E and FIG. 4F, the current blocking layer 69 is grown on the second cladding layers, 50a and 51a, as the mask 67 is left. The blowing layer 69, not grown on the mask 67, is grown on the first portion 51b of the second cladding layer 51a and on the first portion 50b of the third cladding layer 60a. Due to this growth, the second portions 50c and 51c of respective cladding layers, 50a and 51a, which shapes the ridge, are buried with the blocking layer 69. The blocking layer 69 concentrates carriers injected from the electrodes into the second portion 51c with the ridge. This blocking layer 69 may be made of a material with high resistivity or a semiconductor material with a conduction type opposite to that of the second cladding layer 51a.

Subsequent to the growth of the current blocking layer 69, the fourth cladding layer 71 is grown on the second and third cladding layers 51a and 50a, and the current blocking layer 69, as shown in FIG. 5A and FIG. 6B. Next, the contact layer 73 is grown on the first region 41a. The conduction type of the fourth cladding layer 71 and that of the contact layer 73 are same with the second cladding layer 51a. Finally, as shown in FIG. 5c and FIG. 5D, the first electrode 75 is formed on the contact layer 73, while the second eloctrode 77 is on the back side of the GaAs substrate 41, thus completes the optical integrated device 79.

In the optical integrated device 79, the core layer and the third cladding layer, both for the second device 2, are formed on the first cladding layer after growth of the active layer including the quantum well structure for the first device. Therefore, the thickness of the core layer may be equal to that of the active layer, which reduces the reflection inevitably occurred at the interface between the first and second devices.

Moreover, the present optical device has the following advantages considering the structure and the process thereof into account:

(1) The dispersion of the device characteristics can be reduced within the GaAs wafer on which device is formed. Since the care layer of the conventional arrangement includes ternary or more complicated materials such as GaInNAs, the composition thereof tends to be inhomogeneous, which affects the optical characteristics of the waveguide formed on the GaAs wafer.

The dispersion of the device characteristic depending on the shape of the waveguide can be reduced. In the conventional arrangement of the butt-joint structure, the composition and the thickness of the core layer vary at the jointing region, which inevitably appears a step. Therefore, depending on the plane shape of the waveguide, the characteristics of the integrated device change and the dispersion thereof becomes large. Therefore, the process conditions for the waveguide must be redesigned for respective plane shapes of the waveguide.

(3) The optical loss occurred at the interface between the active and passive devices may be decreased. For the conventional butt-joint structure, the source material in gaseous phase made turbulence at the step of the butt joint, which increases the dicontinuity at the interface and accordingly the optical coupling loss thereat.

(4) The dispersion of the coupling loss may be reduced between the active and passive devices depending of the plane shape of the waveguide. The conventional butt-joint configuration varies the composition and the thickness of the waveguide at the joint inevitably varies, which increases the dispersion of the optical coupling loss.

Moreover, the ridge waveguide formed in the present device is unnecessary to etch the active layer and the core layer to confine the transverse mode of the light, so the degradation of the device does not occur due to this etching, thus enhancing the reliability of the device. Further, the optical confinement in the horizontal direction, parallel to the layer direction, is moderate, which increases the exudation of light from the waveguide. When the present device is applied to the directional coupler in the optical add-drop device, the spacing between waveguides to be coupled with each other may be expanded, which increases the margin and decreases the dispersion of the coupling efficiency between the waveguides.

### Third Embodiment

FIG. 6A is a perspective view showing another optical integrated device 101 according to the third embodiment of the invention, and FIG. 6B is a schematic diagram showing an active layer structure.

The optical integrated device 101 provides a similar structure to those shown in the previously explained device 1 except that the device 101 provides a mesa 117 that includes the active layer 109, a portion of the first and second cladding layers 105 and 107, and optical confinement layers 111 and 113, while only the upper cladding layer makes the ridge in the first embodiment. The active layer 109 includes the quantum well structure 112.

The current blocking layer 115 in this device 101, disposed on the fist portion 105b of the first cladding layer 105 to bury the mesa 117a and 117b, which is called as the buried hetero-structure. The current blocking layer 115 may include a reverse-biased pn-junction, that is, the current blocking layer 115 includes a first blocking layer 115a with the second conduction type and a second blocking layer 115b with the first conduction type provided on the first blocking layer 115a. The pn-junction thus formed is biased in reverse when the active layer 109 accompanied with the first and second cladding layers, 105 and 107 are biased in forward Accordingly, substantially no leak current flow in the current blocking layer 115, which concentrates carries injected from the electrode into the mesa 117.

The current blocking layer 115 may be AlGaIP, GaInP, and AlGaAs, these semiconductor materials show band-gap energy greater than that of InP, thereby enhancing the current blocking characteristic.

The optic integrated device 101 may be formed by the same semiconductor materials as those of the first embodiment 1. For instance, semiconductor materials for the first to fourth cladding layers, 105, 107, 114 and 19, for the first and second optical confinement layers, 111 and 113, and for the well layers and barrier layers, 27 and 29, for the contact layer 21, all of which may be same as those used in the first optical device 1. Moreover, the active layer 109 has the multi-quantum well structure as shown in FIG. 6B and smoothly connects the core layer 110 of the second device 101b with the butt-joint structure. The light generated in the first device 101a may enter the second device 101b after slightly reflected at the interface, and the light processed in the second device 101b also enters the first device after sightly reflected at the interface.

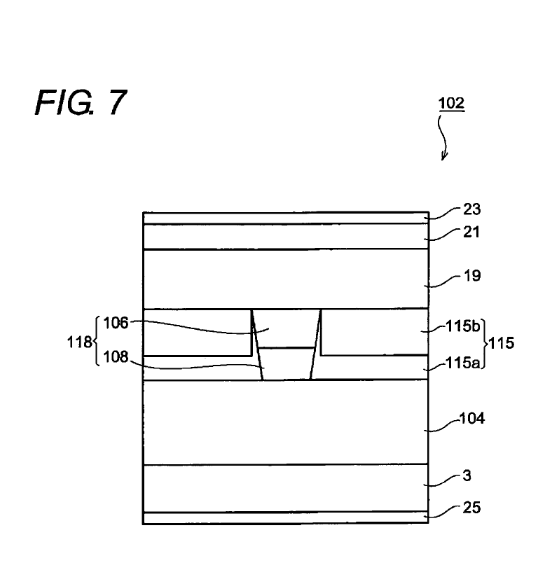

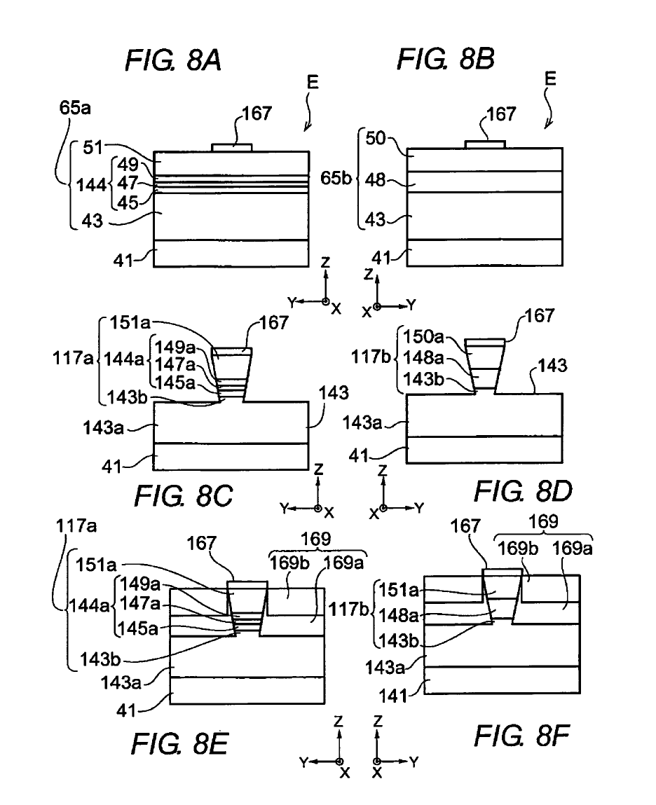

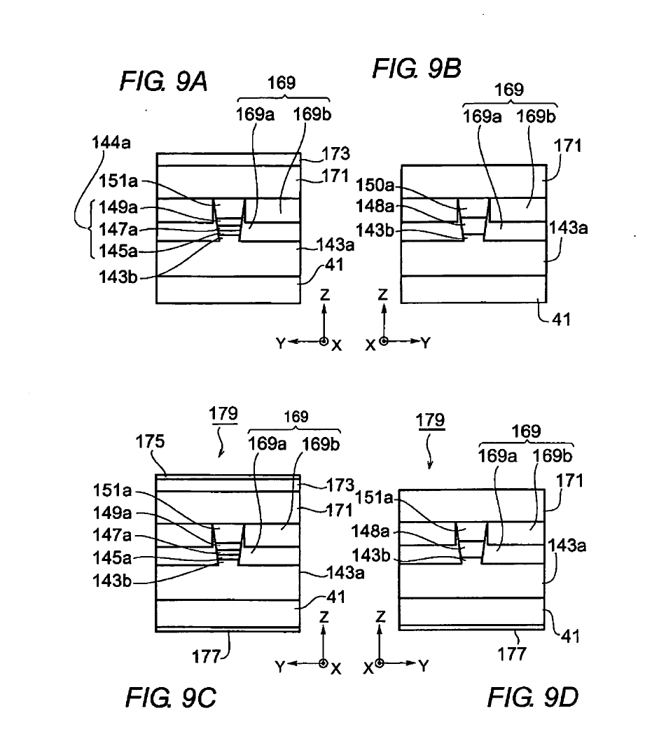

FIG. 7 is a cross section showing a modified structure of the optical integrated device 102 compared to that shown in FIG. 6A The optical integrated device 102 has a mesa 118 including the active layer 108 and the second cladding layer 106. The mesa 118 excludes the first cladding layer 104 in this optical device 102. By selecting the semiconductor material of the first cladding layer 104 and materials used in the mesa 118, the mesa 118 may be easily etched in selective to the first cladding layer 104.

For example, the second cladding layer 106 may be AlGaInP and GaInP, the optical confinement layers, 112 and 114, may be AlGaAs, GaAs, and GaInNAsP lattice matched to the GaAs, and the quantum well layers may be GaNAs, GaInNAs, GaNAsSb, GaNAsP, GaNAsSbP, GaInNAsSb, GaInNAsP or GaInNAsSbP. The barrier layers may be GaAs and GaInAs. When the cladding layer, the active layer and the optical confinement layers are made of materials mentioned above, by using a hydrochloric acid solution, the active layer 108 may be selectively etched to the first cladding layer 104. Thus, the mesa structure 118 shown in FIG. 7 can be easily obtained.

In this process of selectively etching the mesa 118, since the first cladding layer 104 operates as an etch-stopping layer, the mesa 118 may be formed with good reproducibility and homogeneity. The width of the mesa 118 depends on the thickness thereof, accordingly, the selective etching process mentioned above improves the reproducibility and the homogeneity of width of the mesa.

### Fourth Embodiment

As described previously, semiconductor layers of the first cladding layer 43, the active layer 44 that includes a plurality of well and barrier layers and the first and second confinement layers, 45 and 49, the second cladding layer 61 and the cap layer 53 are successively grown on the GaAs substrate 41. On the GaAs substrate 41 is provided with a first region 41a for the first device and a second region 41b for the second device.

Next, the process for manufacturing the optical device using this epitaxial layers E will be explained. An insulating film 167 made of SiO₂ or SiN is formed on the top surface of the layers E.

By using this insulating film 167, the second and third cladding layers, 51 and 50, the active layer 47, core layer 48, and a portion of the first cladding layer 43 are etched, thus forms mesas 117a and 117b. The former mesa 117a includes the second cladding layer 151a and the active layer 144a, while the latter mesa 117b includes the third cladding layer 160a and the care layer 148a. The partly etched first cladding layer 143 comprises the first portion 143a covering the GaAs wafer 41 and the second pardon 143b arranged on the first portion 143a. The second portion 143b appears as a stripe extending along the axis A and is included in respective mesas, 117a and 117b. The cross section of the mesa 117 depends on the crystallographic orientation of the mesa and on the etchant forming the mesa.

As shown in FIG. 8E and FIG. 8F, the current blocking layer 169 is grown selectively only on the flat portion 148a of the first cladding layer 143 without removing the insulating film 167, which buries the mesas, 117a and 117b. The blocking layer 169 comprises the first layer 169a showing the same conduction type with the second cladding layer 151a and the second layer 169b, disposed on the first layer 169a, showing the same conduction type with the first cladding layer 143a. When the active layer is forwardly biased, these two blocking layers, 169a and 169b, are biased in backward, which forms a large built in potential at the interface therebetween, thus preventing carriers from flowing therethrough, accordingly, concentrating carriers into the mesa 117. In a modification, the current blocking layer 169 may be a material with high resistivity.

Subsequent to the process for burying the mesa 117 by the current blocking layer 169, the second epitaxial growth of the fourth cladding layer 171 and the contact layer 173 is carried out on the second and third cladding layers, 151a and 150a. The conduction type of the fourth cladding layer 171 and that of the contact layer 173 are the same with the second cladding layer 151a. Finally, as shown in FIG. 9C and FIG. 9D, the first and second electrodes, 175 and 177, are formed on the contact layer 173 and the back surface of the GaAs wafer 41, respectively, thus completing the optical integrated device 179.

The optical device 179 has similar advantages to those already explained accompanying with the first embodiment. That is, the core layer and the third cladding layer is formed on the first cladding layer after the growth of the active layer for the first device also on the first cladding layer. Therefore, the thickness of the core layer may be substantially identical with that of the active layer in the first device. Thus, the reflection occurred at the interface between the first and second devices may be substantially prevented.

According to the present invention, the active device and the passive device may be monolithically integrated. The active device may be a semiconductor light emitting diode, a semiconductor laser diode, a semiconductor amplifier, a semiconductor optical modulator of an electro-absorption type, a semiconductor optical modulator of a Mach-Zehnder type, and a semiconductor photodiode. The passive device may be an optical waveguide with a straight configuration or with a curved configuration, and an opal coupler such as an optical Y-branch device, an optical directional coupler, a multi-mode interference device (MMI), and an arrayed waveguide (AWG).

While the invention has been particularly shown and described with references to preferred embodiments thereof it will be understood by those skilled in the art that various changes in form and details may be made therein without departing from the spirit and scope of the invention as defined by the appended claims.

1. An optical integrated device, comprising:
a substrate made of GaAs, said core layer having a first region and a second region, said first and second regions being disposed along a prescribed axis;
a first cladding layer having a first portion arranged on said first region and a second portion arranged on said second region, said first cladding layer showing a first conduction type;
a active layer arranged on said first portion of said first cladding layer, said active layer including a quantum well structure with band-gap energy smaller than 1.3 eV;
a second cladding layer arranged on said active layer;
a core layer made of GaAs and arranged on said second portion of said first cladding layer, said core layer being butt-jointed to said active layer; and
a third cladding layer arranged on said core layer.

2. The optical integrated device according to claim 1,
wherein a thickness of said core layer is substantially equal to a thickness of said active layer.

3. The optical integrated device according to claim 1,
wherein said active layer further includes an optical confinement layer sandwiched between at least one of said active layer and said first cladding layer, or said active layer and said second cladding layer, and
wherein said care layer butt-joints to said quantum well structure of said active layer and said opal confinement layer.

4. The optical integrated device according to claim 1,
wherein said active layer has a group III-V compound semiconductor material composing at least nitrogen (N).

5. The optical integrated device according to claim 1,
wherein said first cladding layer is made of GaInP lattice matching to GaAs.

6. The optical integrated device according to claim 1,
wherein said core layer includes a first GaAs layer having said first conduction type and a second GaAs layer having a second conduction type opposite to said first conduction type, said second GaAs layer being arranged between said second portion of said first cladding layer and said first GaAs layer to form a junction.

7. The optical integrated device according to claim 1,
wherein said active layer has an end surface having (111) crystallographic surface and optically coupling with said core layer, said core layer covering said end surface.
